(19) United States
(12) Patent Application Publication
(10) Pub. No.: US 2024/0363813 A1
(43) Pub. Date: Oct. 31, 2024

(54) LIGHT-EMITTING SUBSTRATE AND DISPLAY APPARATUS

(71) Applicant: BOE Technology Group Co., Ltd., Beijing (CN)

(72) Inventors: Xuefei SUN, Beijing (CN); Tingting ZHOU, Beijing (CN); Qian JIA, Beijing (CN); Yingtao WANG, Beijing (CN); Haokun LI, Beijing (CN); Xinxing WANG, Beijing (CN); Jaegeon YOU, Beijing (CN)

(21) Appl. No.: 18/766,710

(22) Filed: Jul. 9, 2024

Related U.S. Application Data
(63) Continuation of application No. PCT/CN2023/084850, filed on Mar. 29, 2023.

(51) Int. Cl. H01L 33/58; H01L 25/16; H01L 33/06

(52) U.S. Cl. CPC H01L 33/58; H01L 25/167; H01L 33/06

(57) ABSTRACT

Provided in the present disclosure are a light-emitting substrate and a display apparatus. The light-emitting substrate includes: a driving backplane; a plurality of light-emitting chips, arranged on the driving backplane in an array, where the light-emitting chip includes a buffer layer, an N-type semiconductor layer, a multi-quantum well layer, and a P-type semiconductor layer sequentially arranged on the driving backplane in a stacked manner; and a grating structure, on a side of the plurality of light-emitting chips facing away from the driving backplane, where the grating structure has a plurality of regions, and the regions are configured to transmit light of different wavelength bands.

### CROSS REFERENCE TO RELATED APPLICATIONS

The present disclosure is a continuation application of International Application No. PCT/CN2023/084850, filed Mar. 29, 2023, which is hereby incorporated by reference in its entirety.

### TECHNICAL FIELD

The present disclosure relates to the field of display technologies, and in particular to a light-emitting substrate and display apparatus.

### BACKGROUND

Epitaxial growth and processing technology based on micro-nano structure, transfer printing technology (i.e., mass transfer technology), and color conversion technology have become the main technological development direction for realizing full-color Micro-LED. However, with the increasingly high resolution requirements of display products, the size of the Micro-LED chip needs to be further reduced, and the size of the RGB color film layer also needs to be further reduced, which poses a very tough challenge to the patterns of the RGB color film layer.

### SUMMARY

The present disclosure provides a light-emitting substrate and display apparatus. The specific schemes are as follows.

The present disclosure provides a light-emitting substrate, including:
a driving backplane;
a plurality of light-emitting chips, arranged on the driving backplane in an array, where each light-emitting chip includes a buffer layer, an N-type semiconductor layer, a multi-quantum well layer, and a P-type semiconductor layer sequentially arranged on the driving backplane in a stacked manner; and
a grating structure, on a side of the plurality of light-emitting chips facing away from the driving backplane, where the grating structure has a plurality of regions, and the plurality regions is configured to transmit light of different wavelength bands.

In a possible implementation, in the above light-emitting substrate provided by embodiments of the present disclosure, each region in the grating structure satisfies at least one of:
each region corresponding to a different grating period;
each region corresponding to a same grating period, each region corresponding to a same grating height, and each region corresponding to a different grating width; or
each region corresponding to a same grating period, each region corresponding to a same grating width, and each region corresponding to a different grating height.

In a possible implementation, in the above light-emitting substrate provided by embodiments of the present disclosure, the plurality of regions is provided in one-to-one correspondence with the light-emitting chip, or the plurality of regions are provided in correspondence with one light-emitting chip.

In a possible implementation, in the above light-emitting substrate provided by embodiments of the present disclosure, the plurality of regions include a first region, a second region, and a third region; the first region is configured to transmit light of a first wavelength band, the second region is configured to transmit light of a second wavelength band, the third region is configured to transmit light of a third wavelength band; a wavelength of the first wavelength band is greater than a wavelength of the second wavelength band, and the wavelength of the second wavelength band is greater than a wavelength of the third wavelength band.

In a possible implementation, in the above light-emitting substrate provided by embodiments of the present disclosure, the grating structure includes a first metal layer, a dielectric layer, and a metal line grid layer sequentially arranged in a stacked manner, and the metal line grid layer includes a plurality of metal lines arranged at intervals.

In a possible implementation, in the above light-emitting substrate provided by embodiments of the present disclosure, a grating period of the metal line grid layer corresponding to the first region, a grating period of the metal line grid layer corresponding to the second region, and a grating period of the metal line grid layer corresponding to the third region sequentially decrease.

In a possible implementation, in the above light-emitting substrate provided by embodiments of the present disclosure, a gap between adjacent metal lines has a same width, and a width of a metal line corresponding to the first region, a width of a metal line corresponding to the second region, and a width of a metal line corresponding to the third region sequentially decrease; or
all the metal lines have the same width, a width of a gap between adjacent metal lines corresponding to the first region, a width of a gap between adjacent metal lines corresponding to the second region, and a width of a gap between adjacent metal lines corresponding to the third region sequentially decrease.

In a possible implementation, in the above light-emitting substrate provided by embodiments of the present disclosure, the first metal layer is proximate to the light-emitting chip; or
the metal line grid layer is proximate to the light-emitting chip, and the grating structure further includes a second metal layer between the metal line grid layer and the light-emitting chip.

In a possible implementation, in the above light-emitting substrate provided by embodiments of the present disclosure, the first metal layer is proximate to the light-emitting chip, grating periods of the metal line grid layer respectively corresponding to the first region, the second region, and the third region are the same, and a width of a metal line corresponding to the first region, a width of a metal line corresponding to the second region and a width of a metal line corresponding to the third region sequentially decrease.

In a possible implementation, in the above light-emitting substrate provided by embodiments of the present disclosure, the first metal layer is proximate to the light-emitting chip, grating periods of the metal line grid layer respectively corresponding to the first region, the second region, and the third region are the same, widths of the plurality of metal lines are the same, and a height of a metal line corresponding to the first region, a height of a metal line corresponding to the second region and a height of a metal line corresponding to the third region sequentially decrease.

In a possible implementation, in the above light-emitting substrate provided by embodiments of the present disclosure, the grating structure includes a first metal layer, a dielectric line grid layer, and a third metal layer sequentially arranged in a stacked manner, the dielectric line grid layer includes a plurality of dielectric lines arranged at intervals, a grating period of the dielectric line grid layer corresponding to the first region, a grating period of the dielectric line grid layer corresponding to the second region and a grating period of the dielectric line grid layer corresponding to the third region sequentially decrease.

In a possible implementation, in the above light-emitting substrate provided by embodiments of the present disclosure, a material of the dielectric line grid layer includes SiO or SiN.

In a possible implementation, in the above light-emitting substrate provided by embodiments of the present disclosure, a material of the dielectric line grid layer is a rigid substrate material or a flexible substrate material, the grating structure further includes a first substrate between the dielectric line grid layer and the third metal layer, and the first substrate and the dielectric line grid layer are a one-piece structure.

In a possible implementation, in the above light-emitting substrate provided by embodiments of the present disclosure, the driving backplane is a silicon-based driving backplane, and the light-emitting chip is a Micro LED or Mini LED.

Correspondingly, embodiments of the present disclosure provide a display apparatus, including the above light-emitting substrate provided in the embodiments of the present disclosure.

### BRIEF DESCRIPTION OF FIGURES

FIG. 1 shows a schematic structural diagram of a light-emitting substrate provided by embodiments of the present disclosure.

FIG. 2 shows a schematic structural diagram of yet another light-emitting substrate provided by embodiments of the present disclosure.

FIG. 3 shows a schematic structural diagram of yet another light-emitting substrate provided by embodiments of the present disclosure.

FIG. 4 shows a schematic structural diagram of yet another light-emitting substrate provided by embodiments of the present disclosure.

FIG. 5 shows a schematic structural diagram of yet another light-emitting substrate provided by embodiments of the present disclosure.

FIG. 6 shows a schematic structural diagram of yet another light-emitting substrate provided by embodiments of the present disclosure.

FIG. 7A-FIG. 7C are schematic structural diagrams of manufacturing the light-emitting substrate shown in FIG. 4 after performing each step, respectively.

FIG. 8A-FIG. 8D are schematic structural diagrams of manufacturing the light-emitting substrate shown in FIG. 6 after performing each step, respectively.

FIG. 9 shows a schematic diagram of the variation of the transmittance (T₀) of different wavelength bands of light (μm) with the grating period.

FIG. 10 shows a schematic diagram of the variation of the transmittance (T₀) of different wavelength bands of light (μm) with the width of the metal line in the grating structure.

FIG. 11 shows a schematic diagram of the variation of the transmittance (T₀) of different wavelength bands of light (μm) with the height of the metal line in the grating structure.

### DETAILED DESCRIPTION

In order to make the objectives, technical solutions and advantages of the embodiments of the present disclosure clearer, the technical solutions of the embodiments of the present disclosure will be described clearly and completely in the following in conjunction with the drawings of the embodiments of the present disclosure. Obviously, the described embodiments are a part of the embodiments of the present disclosure and not all of the embodiments. And the embodiments and the features in the embodiments of the present disclosure can be combined with each other without conflict. Based on the described embodiments of the present disclosure, all other embodiments obtained by a person of ordinary skill in the art without the need for creative labor are within the protection scope of the present disclosure.

Unless otherwise defined, technical terms or scientific terms used in the present disclosure shall have the ordinary meaning understood by a person of ordinary skill in the field to which the present disclosure belongs. The words “including” or “comprising” and the like as used in the present disclosure are intended to mean that the element or object appearing before the word covers the element or object appearing after the word and its equivalents, and does not exclude other elements or objects. Words such as “connected” or “coupled” are not limited to physical or mechanical connections, but may include electrical connections, whether direct or indirect. The words “inside”, “outside”, “above”, “below”, etc. are only used to indicate relative positional relationships. When the absolute position of the depicted object is changed, then the relative positional relationships may also be changed accordingly.

It should be noted that the dimensions and shapes of the figures in the accompanying drawings do not reflect true proportions and are intended to illustrate the present disclosure only. And the same or similar labeling throughout denotes the same or similar elements or elements having the same or similar functions.

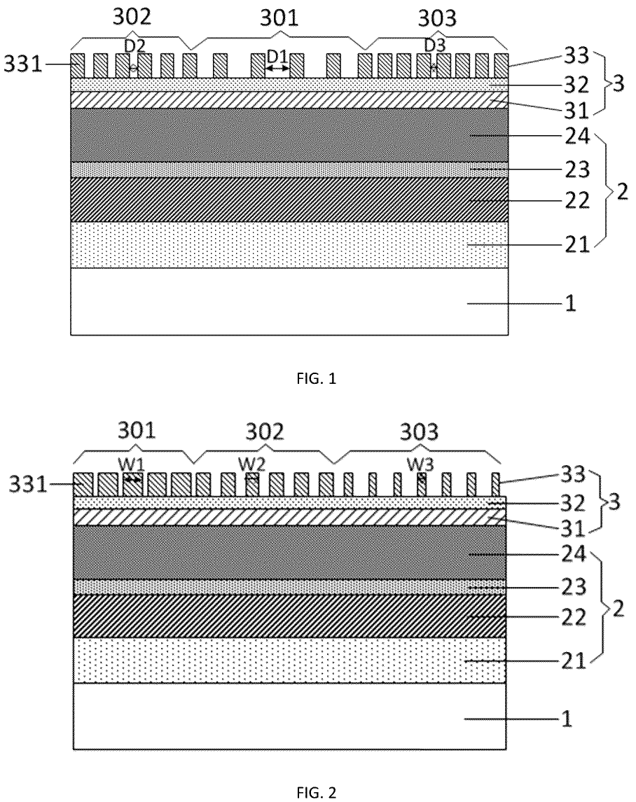

The present disclosure provides a light-emitting substrate, as shown in FIG. 1-FIG. 6, including:
a driving backplane 1;
a plurality of light-emitting chips 2 (LEDs), arranged on the driving backplane 1 in an array; FIG. 1-FIG. 6 of the present disclosure illustrate a sectional schematic of only one light-emitting chip 2, and the light-emitting chip includes a buffer layer 21, an N-type semiconductor layer 22, a multi-quantum well layer 23, and a P-type semiconductor layer 24, which are sequentially arranged on the driving backplane 1 in a stacked manner; and
a grating structure 3, on a sides of the plurality of light-emitting chips 2 facing away from the driving backplane 1, where the grating structure 3 includes a plurality of regions (301, 302, and 303), and the regions (301, 302, and 303) are configured to transmit light of different wavelength bands.

The above light-emitting substrate provided by the embodiments of the present disclosure, using the design of LED+grating structure, can realize the transmission of different wavelength bands of light, and realize the preparation of high-quality color LED devices; moreover, by adopting the grating structure instead of the traditionally-used color film layer, it can solve the problem that the difficulty of the process of manufacturing the color film layer of different colors is greatly increased due to the improvement of the resolution; moreover, the grating structure in the present disclosure can filter out the stray light in each wavelength band of light, thereby further purifying the light of each wavelength band to enhance the color purity; furthermore, since the regions of the grating structure are configured to transmit the light of different wavelength bands, the problem of stringing of colors in adjacent regions can also be avoided.

In specific implementation, in order to enable the grating structure to replace the role of the conventional color film layer, in the above light-emitting substrate provided by embodiments of the present disclosure, as shown in FIG. 1-FIG. 6, the respective regions (301, 302, and 303) in the grating structure 3 satisfy at least one of the following:
each region (301, 302 and 303) corresponds to a same grating period;
each region (301, 302 and 303) corresponds to a same grating period, each region (301, 302 and 303) corresponds to a same grating height, and each region (301, 302 and 303) corresponds to a different grating width; or
each region (301, 302 and 303) corresponds to a same grating period, each region (301, 302 and 303) corresponds to a same grating width, and each region (301, 302 and 303) corresponds to a different grating height.

In specific implementation, in the above light-emitting substrate provided by embodiments of the present disclosure, as shown in FIG. 1-FIG. 6, the plurality of regions (e.g., 301, 302, and 303) are provided in correspondence with one light-emitting chip 2; of course, it is also possible that the various regions (301, 302, and 303) are provided in one-to-one correspondence with the light-emitting chips 2.

In specific implementation, in the above light-emitting substrate provided by embodiments of the present disclosure, as shown in FIG. 1-FIG. 6, the plurality of regions (301, 302 and 303) include a first region 301, a second region 302, and a third region 303, the first region 301 is configured to transmit light of a first wavelength band, the second region 302 is configured to transmit light of a second wavelength band, the third region 303 is configured to transmit light of a third wavelength band, a wavelength of the first wavelength band is greater than a wavelength of the second wavelength band, and the wavelength of the second wavelength band is greater than a wavelength of the third wavelength band. Specifically, for example, the first wavelength band is a red light band (R), the second wavelength band is a green light band (G), and the third wavelength band is a blue light band (B), so as to achieve the preparation of a high-quality color LED device.

It should be noted that the grating structure provided by the embodiments of the present disclosure is not limited to including the first region 301, the second region 302, and the third region 303, but may also include other regions, for example, the other regions may be configured to transmit a white light band or a yellow light band, etc., respectively, and the present disclosure is not limited thereto.

In specific implementation, in the above light-emitting substrate provided by embodiments of the present disclosure, as shown in FIG. 1-FIG. 4, the grating structure 3 includes a first metal layer 31, a dielectric layer 32, and a metal line grid layer 33 sequentially arranged in a stacked manner, and the metal line grid layer 33 includes a plurality of metal lines 331 arranged at intervals.

Specifically, the material of the first metal layer 31 includes, but is not limited to, Au, Ag, Al, or Mo, etc., and a thickness of the first metal layer 31 is less than 0.2 mm; a material of the dielectric layer 32 includes, but is not limited to, SiO, SiN, etc.; and a material of the metal line grid layer 33 includes, but is not limited to, Au, Ag, Al, or Mo, etc., and a thickness of the metal line grid layer 33 may be 10 nm to 500 nm.

Optionally, as shown in FIG. 1-FIG. 4, the grating structure 3 can achieve selective transmission of the light emitting color, i.e., the grating structure 3 can transmit light of a specific wavelength band. Generally, by adjusting the grating period (a sum of a width of the metal line and a width of a gap between adjacent metal lines), the grating height, or the grating width of the metal line grid layer, the light of a given color (a given wavelength A) can be realized to be emitted in a direction of light emission. For example, the light-emitting chip can be a white light-emitting chip, then the white light emitted from the white light-emitting chip is incident and passes through the grating structure 3 to transmit the three monochromatic light of red, green, blue, so as to emit the predetermined color of the light. For example, the light-emitting chip 2 may include a red light-emitting chip, a green light-emitting chip, and a blue light-emitting chip, the red light-emitting chip, the green light-emitting chip, and the blue light-emitting chip respectively emit red light, green light, and blue light, and the red light, green light and blue light are respectively incident through the corresponding regions of the grating structure 3 to output the purer red monochromatic light, the purer green monochromatic light and the purer blue monochromatic light. In embodiments of the present disclosure, the grating period can be 400 nm-600 nm, and the light-emitting chip of each color can transmit light of a predetermined color by setting the corresponding grating period, grating height, or grating width, and because the corresponding grating period of each light-emitting chip is generally small, the size of each light-emitting chip can be made very small, so as to achieve a high-resolution display. Since the grating structure 3 in the embodiments of the present disclosure has the role of selective transmission of the light emitting color, the light-emitting substrate provided in the embodiments of the present disclosure can omit the color film layer in the traditional scheme, and not only can it realize a colorful display, but also enhance the color purity, and it can also avoid the problem of crosstalk of color in the adjacent regions.

In specific implementation, in the above light-emitting substrate provided by embodiments of the present disclosure, as shown in FIG. 1 and FIG. 4, a grating period of the metal line grid layer 33 corresponding to the first region 301, a grating period of the metal line grid layer 33 corresponding to the second region 302, and a grating period of the metal line grid layer 33 corresponding to the third region 303 sequentially decrease. In this way, when the light-emitting chip 2 is a white light-emitting chip, white light emitted from the light-emitting chip 2 passes through the grating structure 3, so that red monochromatic light of higher purity can be transmitted through the first region 301, green monochromatic light of higher purity can be transmitted through the second region 302, and blue monochromatic light of higher purity can be transmitted through the third region 303; when the light-emitting chip 2 includes a red light-emitting chip, a green light-emitting chip or a blue light-emitting chip, and the red light, green light or blue light emitted from the light-emitting chip 2 passes through the grating structure 3, the first region 301 can filter out stray light for the red light, the second region 302 can filter out stray light for the green light, and the third region 303 can filter out stray light for the blue light, so as to obtain red monochromatic light, green monochromatic light, and blue monochromatic light with a higher degree of color purity.

In specific implementation, in the above light-emitting substrate provided in embodiments of the present disclosure, as shown in FIG. 1 and FIG. 4, the widths of all metal lines 331 are the same, and a width D1 of a gap between adjacent metal lines 331 corresponding to the first region 301, a width D2 of a gap between adjacent metal lines 331 corresponding to the second region 302, and a width D3 of a gap between adjacent metal lines 331 corresponding to the third region 303 are sequentially decrease. This can realize that the grating period of the metal line grid layer 33 corresponding to the first region 301 (transmitting the red light band), the grating period of the metal line grid layer 33 corresponding to the second region 302 (transmitting the green light band), and the grating period of the metal line grid layer 33 corresponding to the third region 303 (transmitting the blue light band) sequentially decrease, thereby realizing that different regions of the grating structure 3 transmit light of different color bands.

Of course, in specific implementation, a gap between adjacent metal lines in the metal line grid layer has the same width, and a width of the metal line corresponding to the first region, a width of the metal line corresponding to the second region, and a width of the metal line corresponding to the third region sequentially decrease, so as to also realize that the grating period of the metal line grid layer corresponding to the first region, the grating period of the metal line grid layer corresponding to the second region, and the grating period of the metal line grid layer corresponding to the third region sequentially decrease.

In specific implementation, in the above light-emitting substrate provided in embodiments of the present disclosure, as shown in FIG. 1, the first metal layer 31 is close to the light-emitting chip 2, so that the light-emitting chip 2 can be transferred to the driving backplane 1 first, and then the first metal layer 31, the dielectric layer 32, and the metal line grid layer 33 can be manufactured above the light-emitting chip 2 sequentially.

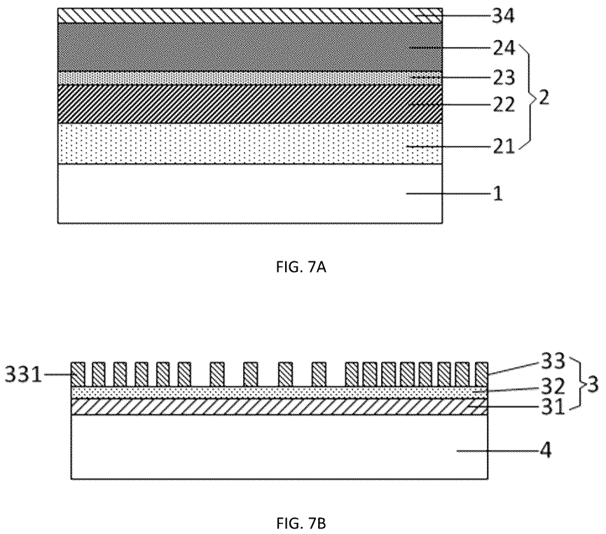

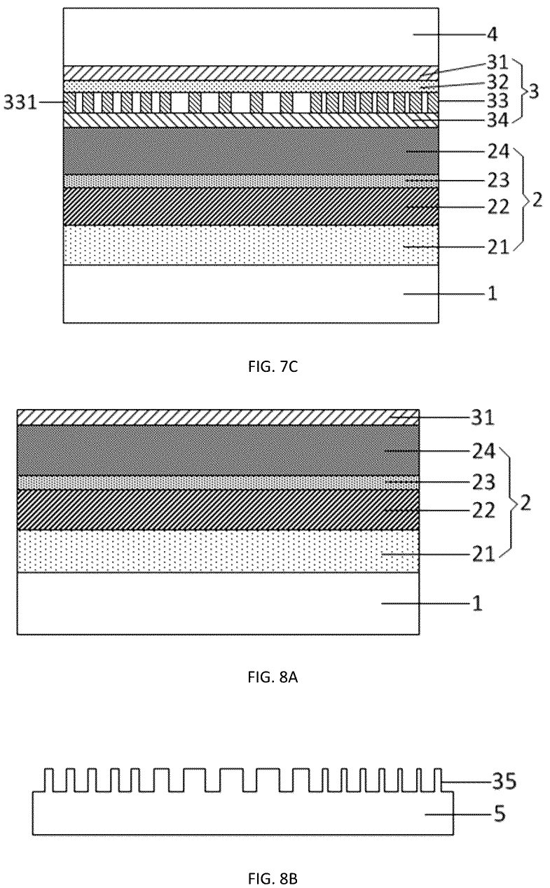

In specific implementation, in the above light-emitting substrate provided by embodiments of the present disclosure, as shown in FIG. 4, the metal line grid layer 33 is close to the light-emitting chip 2, and the grating structure 3 also includes a second metal layer 34 between the metal line grid layer 33 and the light-emitting chip 2. In this way, it is possible to transfer the light-emitting chip 2 to the driving backplane 1 first, and then manufacture the second metal layer 34 on the light-emitting chip 2, as shown in FIG. 7A; the first metal layer 31, the dielectric layer 32, and the metal line grid layer 33 are sequentially manufactured on a base substrate, as shown in FIG. 7B; the structure shown in FIG. 7B is bonded to the structure shown in FIG. 7A by a transfer printing process, as shown in FIG. 7C; and finally the base substrate 4 is removed to obtain the light-emitting substrate shown in FIG. 4.

Specifically, the material of the base substrate 4 may be a rigid material, such as glass; or a flexible material, such as polyimide, etc.

In specific implementation, in the above light-emitting substrate provided by embodiments of the present disclosure, as shown in FIG. 2, the first metal layer 31 is close to the light-emitting chip 2, the grating periods of the metal line grid layer 33 respectively corresponding to the first region 301, the second region 302, and the third region 303 are the same, and the width W1 of the metal line 331 corresponding to the first region 301, the width W1 of the metal line 331 corresponding to the second region 302, and the width W3 of the metal line 331 corresponding to the third region 303 sequentially decrease. In this way, by adjusting the widths of the metal lines 331 in different regions, it is also possible to realize that the first region 301 transmits light of the red light band, the second region 302 transmits light of the green light band, and the third region 303 transmits light of the blue light band. The transmittance principle of the grating structure 3 shown in FIG. 2 for different wavelength bands of light is the same as the transmittance principle of FIG. 1 and FIG. 4, and will not be repeated herein.

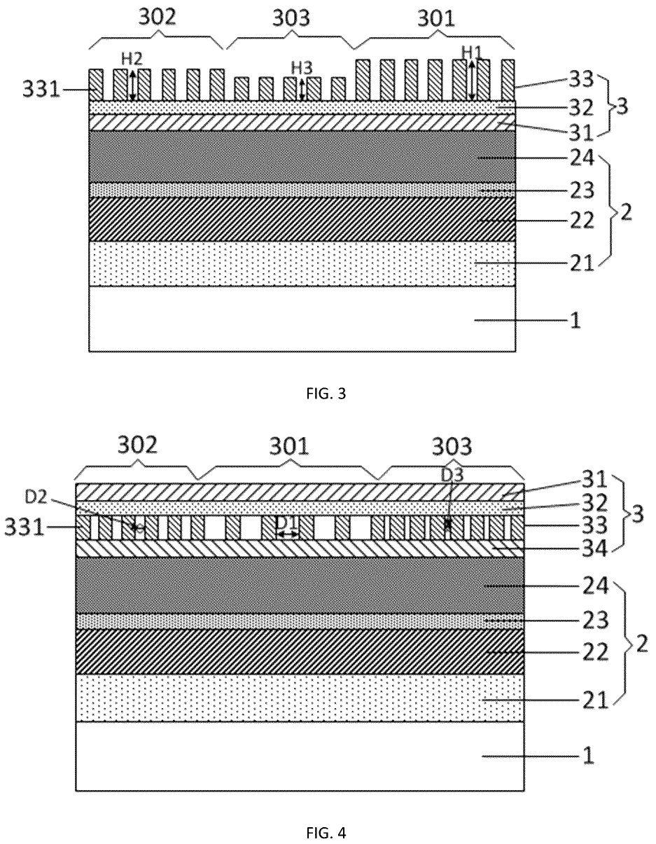

In specific implementation, in the above light-emitting substrate provided in embodiments of the present disclosure, as shown in FIG. 3, the first metal layer 31 is close to the light-emitting chip 2, the grating periods of the metal line grid layer 33 respectively corresponding to the first region 301, the second region 302, and the third region 303 are the same, the widths of the respective metal lines 331 are the same, and the height H1 of the metal line 331 corresponding to the first region 301, the height H2 of the metal line 331 corresponding to the second region 302, and the height H3 of the metal line 331 corresponding to the third region 303 sequentially decrease. In this way, by adjusting the heights of the metal lines 331 in different regions, it is also possible to realize that the first region 301 transmits light of the red light band, the second region 302 transmits light of the green light band, and the third region 303 transmits light of the blue light band. The transmittance principle of the grating structure 3 shown in FIG. 3 for different wavelength bands of light is the same as the transmittance principle of FIG. 1 and FIG. 4, and will not be repeated herein.

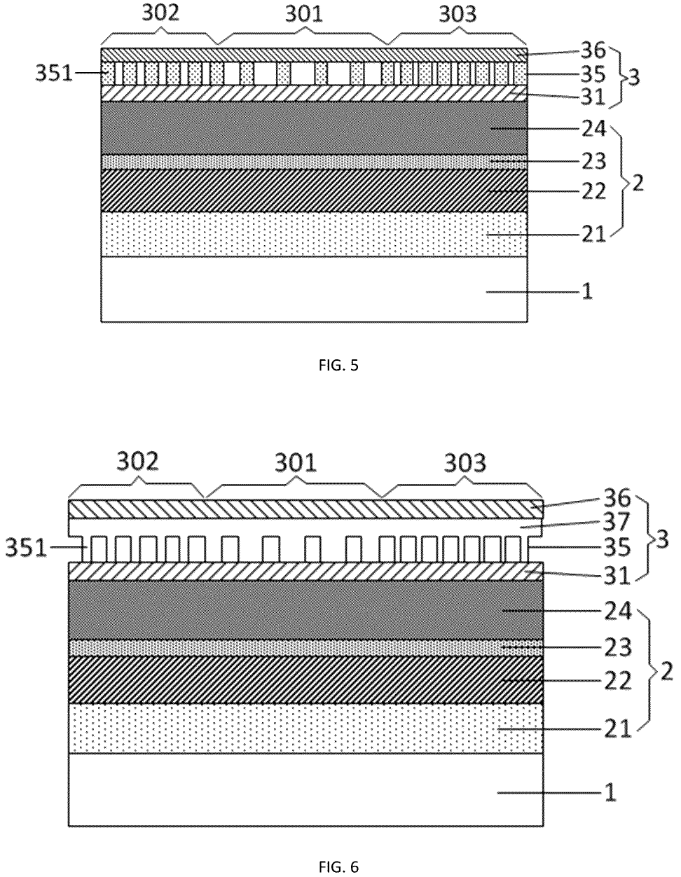

In specific implementation, in the above light-emitting substrate provided in embodiments of the present disclosure, as shown in FIG. 5 and FIG. 6, the grating structure 3 includes a first metal layer 31, a dielectric line grid layer 35, and a third metal layer 36 sequentially arranged in a stacked manner, the dielectric line grid layer 35 includes a plurality of dielectric lines 351 arranged at intervals, a grating period of the dielectric line grid layer 35 corresponding to the first region 301, a grating period of the dielectric line grid layer 35 corresponding to the second region 302, and a grating period of the dielectric line grid layer 35 corresponding to the third region 303 sequentially decrease. Specifically, the grating period of the grating structure 3 shown in FIG. 5 is set in the same manner as that of the structure shown in FIG. 1, and the difference between the grating structure 3 shown in FIG. 5 and the grating structure 3 shown in FIG. 1 is that the line grid layer is arranged between two metal layers, and the material of the line grid layer adopts a dielectric material, e.g., the material of the dielectric line grid layer 35 includes, but is not limited to, SiO or SiN, i.e., the grating fabrication process steps of the two are different, but the light transmission principle of the grating structure 3 shown in FIG. 5 and the light transmission principle of the grating structure 3 shown in FIG. 1 are the same, i.e., the optical effect is the same, and will not be repeated herein. As shown in FIG. 6, the material of the dielectric line grid layer 35 may be a rigid substrate material (e.g., glass, etc.) or a flexible substrate material (e.g., polyimide, etc.), and the grating structure 3 further includes a first substrate 37 between the dielectric line grid layer 35 and the third metal layer 36, and the first substrate 37 and the dielectric line grid layer 35 are a one-piece structure, and the light transmission principle of the grating structure 3 shown in FIG. 6 is also the same as that of the grating structure 3 shown in FIG. 1, and will not be repeated herein.

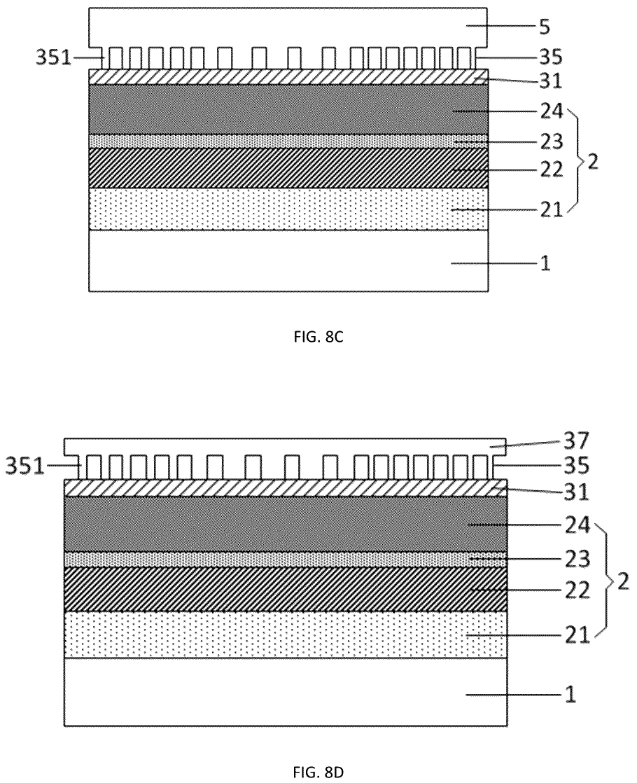

Specifically, the manufacture method of the light-emitting substrate shown in FIG. 6 may be as follows: the light-emitting chip 2 may first be transferred to the driving backplane 1, and then the first metal layer 31 may be manufactured on the light-emitting chip 2, as shown in FIG. 8A; a substrate 5 is provided and a grating may be manufactured for the substrate 5, and the dielectric line grid layer 35 may be formed on the substrate 5, as shown in FIG. 8B; and a structure shown in FIG. 8B may be bonded to the structure shown in FIG. 8A by a transfer printing process, as shown in FIG. 8C; a thinning process is performed on the substrate 5 to obtain the first substrate 37 and the dielectric line grid layer 35 of a one-piece structure, as shown in FIG. 8D; and the third metal layer 36 is formed on the first substrate 37 to obtain the light-emitting substrate shown in FIG. 6.

The principle by which the grating structure 3 is capable of selectively transmitting light of different wavelength bands is hereinafter explained using the light-emitting substrate shown in FIG. 1-FIG. 3 as an example.

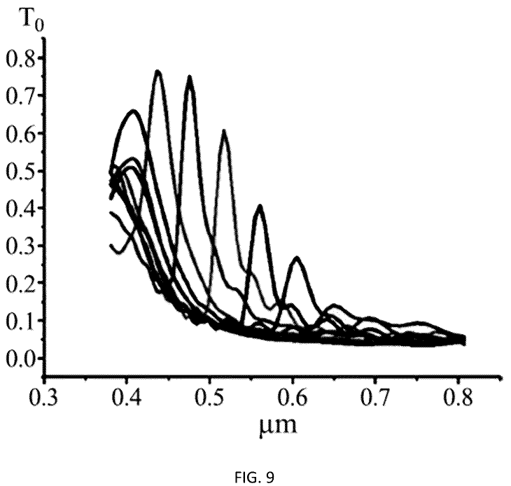

As shown in FIG. 1 and FIG. 9, FIG. 9 is a schematic diagram of the variation of the transmittance (T₀) of different wavelengths of light (μm) with the grating period. For example, the height of the metal line grid layer 33 can be set to 10 nm to 500 nm, and the thickness of the dielectric layer 32 is not limited, and according to the grating formula n₀−n₁=N*λ/T (herein n₀ is the refractive index of the metal line grid layer 33, 71 is the refractive index of the air, N is an integer, λ is the wavelength, and T is the grating period), taking the height of the metal line grid layer 33 is 100 nm, the thickness of the dielectric layer is 80 nm, and the thickness of the first metal layer 31 is 100 nm as an example, the materials of the first metal layer 31 and the metal line grid layer 33 are both Ag, and the range of the grating period can be 400 nm to 600 nm, specifically, when the grating period is 400 nm, the transmittance of the light wavelength of 440 nm is 78%; when the grating period is 450 nm, the transmittance of the light wavelength of 480 nm is 76%; when the grating period is 500 nm, the transmittance of the light wavelength of 520 nm is 63%; when the grating period is 550 nm, the transmittance of the light wavelength of 570 nm is 40%; when the grating period is 600 nm, the transmittance of the light wavelength of 620 nm is 28%. Therefore, by adjusting the grating periods can realize the selective transmission of different wavelengths of light, for example, the grating period corresponding to the red light band, the grating period corresponding to the green light band, and the grating period corresponding to the blue light band sequentially decrease.

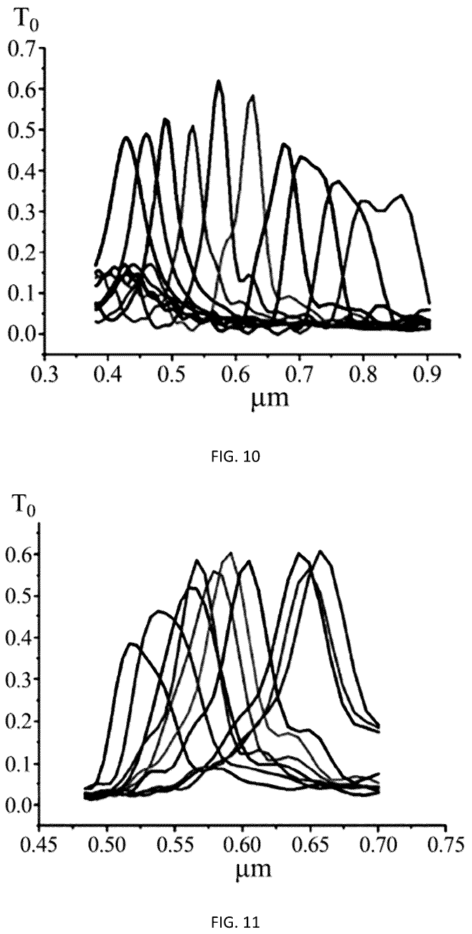

As shown in FIG. 2 and FIG. 10, FIG. 10 shows a schematic diagram of the variation of the transmittance (T₀) of different wavelengths of light (μm) with the width of the metal line in the grating structure. For example, the height of the metal line grid layer 33 is 100 nm, the thickness of the dielectric layer 32 is 80 nm, the thickness of the first metal layer 31 is 100 nm, and the materials of the first metal layer 31 and the metal line grid layer 33 are both Ag, with a grating period of 600 nm as an example, the width of the metal line 331 ranges from 250 nm to 550 nm, specifically, when the width of the metal line 331 is 250 nm, the transmittance of the light wavelength of 420 nm is 50%; when the width of the metal line 331 is 350 nm, the transmittance of the light wavelength of 490 nm is 54%; when the width of the metal line 331 is 450 nm, the transmittance of the light wavelength of 570 nm is 63%; and when the width of the metal line 331 is 550 nm, the transmittance of the light wavelength of 630 nm is 59%. Therefore, keeping the grating period the same, selective transmission of light of different wavelengths can also be realized by adjusting the width of the metal line, for example, the width of the metal line corresponding to the red light band, the width of the metal line corresponding to the green light band, and the width of the metal line corresponding to the blue light band sequentially decrease.

As shown in FIG. 3 and FIG. 11, FIG. 11 shows a schematic diagram of the variation of the transmittance rate (T₀) of different wavelengths of light (μm) with the height of the metal line in the grating structure. The height of the metal line grid layer 33 is 100 nm, the thickness of the dielectric layer 32 is 80 nm, the thickness of the first metal layer 31 is 100 nm, and the materials of the first metal layer 31 and the metal line grid layer 33 are both Ag, with a grating period of 450 nm as an example, the height of the metal line 331 ranges from 50 nm to 150 nm, specifically, when the height of the metal line 331 is 50 nm, the transmittance of the light wavelength of 530 nm is 39%; when the height of the metal line 331 is 100 nm, the transmittance of the light wavelength of 580 nm is 60%; when the height of the metal line 331 is 110 nm, the transmittance of the light wavelength of 600 nm is 56%. Therefore, keeping the grating period the same, selective transmission of light of different wavelengths can be realized by adjusting the height of the metal line, for example, the height of the metal line corresponding to the red light band, the height of the metal line corresponding to the green light band, and the height of the metal line corresponding to the blue light band sequentially decrease.

It should be noted that the grating structures shown in FIG. 4-FIG. 6 have different grating periods corresponding to different regions, so the working principle of the grating structure 3 shown in FIG. 4-FIG. 6 is the same as that shown in FIG. 1, and will not be repeated herein.

In specific implementation, in the above light-emitting substrate provided in embodiments of the present disclosure, the driving backplane may be a silicon-based driving backplane. The driving backplane may include: a substrate, an active layer, a gate insulating layer, a gate, an interlayer insulating layer, a source and a drain, a flattening layer, a first electrode, and a second electrode arranged in a stacked manner between the substrate and the light-emitting chip. The active layer, the gate, the source, and the drain constitute a thin film transistor. The first electrode is electrically connected with the drain through a via hole penetrating through the flattening layer. The second electrode is grounded. Specifically, the first electrode and the second electrode are transfer electrodes (pins) in the case of an outsourced transfer-printed light-emitting chip. The materials of the first electrode and the second electrode are Ag, Au, and the like.

In specific implementation, in the above light-emitting substrate provided by embodiments of the present disclosure, the buffer layer of the light-emitting chip can be gallium nitride, the N-type semiconductor layer can be N-type gallium nitride, and the P-type semiconductor layer can be P-type gallium nitride.

In specific implementation, in the above light-emitting substrate provided by embodiments of the present disclosure, the side of the light-emitting chip facing the driving backplane includes a third electrode (P-type pad) and a fourth electrode (N-type pad), the third electrode is electrically connected with the first electrode, and the fourth electrode is electrically connected with the second electrode. Specifically, when the light-emitting chip emits light, a driving current is input to the light-emitting chip through the thin-film transistor, and the specific light-emitting principle is the same as that of the related art, and will not be described in detail herein.

Specifically, the embodiments of the present disclosure transfer the light-emitting chip to the driving backplane through the transfer electrodes (the first electrode and the second electrode) when manufacturing the light-emitting substrate, and the light-emitting chip is made of an inorganic material, which has a better stability as compared to an organic material.

In specific implementation, in the above light-emitting substrate provided by embodiments of the present disclosure, the light-emitting chip may be a Micro LED, and the pixel resolution of the light-emitting substrate may be improved due to the smaller size of the Micro LED. Specifically, the size of the Micro LED is generally less than 100 μm. Of course, the light-emitting chip may also be other LEDs such as Mini LEDs, and the present disclosure does not limit this. Specifically, when the light-emitting chip is a Mini LED, the size of the Mini LED is 100 μm to 200 μm.

Specifically, the above light-emitting substrate provided by the embodiments of the present disclosure is provided as an example of a display substrate, and of course, it can also be a backlight substrate. If the above light-emitting substrate is a backlight substrate, the light-emitting chip is configured to provide a light source for realizing a display with a passive display panel.

Here, the light-emitting color included in the light-emitting substrate is not limited, the light-emitting color of the light-emitting substrate may include any one of red, green or blue. The light-emitting color of the light-emitting substrate can include red, green or blue light-emitting color at the same time; of course, only one light-emitting color can be included, for example: only including red, or only including green, or only including blue. The details can be determined according to the actual requirements.

In specific implementation, the above light-emitting substrate provided by the embodiments of the present invention may also include other functional film layers known to the persons skilled in the art, which are not listed here.

Based on the same inventive concept, the embodiments of the present invention also provide a display apparatus including any of the above-mentioned light-emitting substrates provided by the embodiments of the present invention. The display apparatus may be: a cellular phone, a tablet computer, a television, a monitor, a laptop computer, a digital photo frame, a navigator, and any other product or component having a display function. The implementation of the display apparatus can be found in the above embodiments of the light-emitting substrate, and the repetition will not be repeated.

The light-emitting substrate and display apparatus provided by the embodiments of the present disclosure, using the design of LED plus grating structure, can achieve the transmission of different wavelengths of light, and realize the preparation of high-quality color LED devices; moreover, by adopting the grating structure instead of the traditionally-used color film layer, it can solve the problem that the difficulty in the process of manufacturing the color film layer of different colors is greatly increased due to the improvement of the resolution; moreover, the grating structure in the present disclosure can filter out stray light in each wavelength band of light, thereby further purifying the light of each wavelength band to enhance the color purity; furthermore, since the regions of the grating structure are configured to transmit the light of different wavelength bands, the problem of stringing of colors in adjacent regions can also be avoided.

Although preferred embodiments of the present disclosure have been described, those skilled in the art may make additional changes and modifications to these embodiments once the basic inventive concepts are known. Therefore, the appended claims are intended to be construed to include the preferred embodiments as well as all changes and modifications that fall within the scope of the present disclosure.

Obviously, a person skilled in the art can make various changes and variations to the presently disclosed embodiments without departing from the spirit and scope of the presently disclosed embodiments. Thus, if such modifications and variations of the presently disclosed embodiments fall within the scope of the presently disclosed claims and their technical equivalents, the present disclosure is intended to include such modifications and variations.

What is claimed is:

1. A light-emitting substrate, comprising:
a driving backplane;
a plurality of light-emitting chips, arranged on the driving backplane in an array, wherein each light-emitting chip comprises a buffer layer, an N-type semiconductor layer, a multi-quantum well layer, and a P-type semiconductor layer sequentially arranged on the driving backplane in a stacked manner; and
a grating structure, on a side of the plurality of light-emitting chips facing away from the driving backplane, wherein the grating structure has a plurality of regions, and the plurality of regions is configured to transmit light of different wavelength bands.

2. The light-emitting substrate according to claim 1, wherein each region in the grating structure satisfies at least one of:
each region corresponding to a different grating period;
each region corresponding to a same grating period, each region corresponding to a same grating height, and each region corresponding to a different grating width; or
each region corresponding to a same grating period, each region corresponding to a same grating width, and each region corresponding to a different grating height.

3. The light-emitting substrate according to claim 2, wherein the plurality of regions is provided in one-to-one correspondence with the light-emitting chip, or the plurality of regions are provided in correspondence with one light-emitting chip.

4. The light-emitting substrate according to claim 3, wherein the plurality of regions comprise a first region, a second region, and a third region; the first region is configured to transmit light of a first wavelength band, the second region is configured to transmit light of a second wavelength band, the third region is configured to transmit light of a third wavelength band; and a wavelength of the first wavelength band is greater than a wavelength of the second wavelength band, and the wavelength of the second wavelength band is greater than a wavelength of the third wavelength band.

5. The light-emitting substrate according to claim 4, wherein the grating structure comprises a first metal layer, a dielectric layer, and a metal line grid layer sequentially arranged in a stacked manner, and the metal line grid layer comprises a plurality of metal lines arranged at intervals.

6. The light-emitting substrate according to claim 5, wherein a grating period of the metal line grid layer corresponding to the first region, a grating period of the metal line grid layer corresponding to the second region, and a grating period of the metal line grid layer corresponding to the third region sequentially decrease.

7. The light-emitting substrate according to claim 6, wherein
a gap between adjacent metal lines has a same width, and a width of the metal line corresponding to the first region, a width of a metal line corresponding to the second region, and a width of a metal line corresponding to the third region sequentially decrease; or
all the metal lines have a same width, a width of a gap between adjacent metal lines corresponding to the first region, a width of a gap between adjacent metal lines corresponding to the second region, and a width of a gap between adjacent metal lines corresponding to the third region sequentially decrease.

8. The light-emitting substrate according to claim 7, wherein the first metal layer is proximate to the light-emitting chip; or
the metal line grid layer is proximate to the light-emitting chip, and the grating structure further comprises a second metal layer between the metal line grid layer and the light-emitting chip.

9. The light-emitting substrate according to claim 5, wherein the first metal layer is proximate to the light-emitting chip, grating periods of the metal line grid layer respectively corresponding to the first region, the second region, and the third region are the same, and a width of a metal line corresponding to the first region, a width of a metal line corresponding to the second region and a width of a metal line corresponding to the third region sequentially decrease.

10. The light-emitting substrate according to claim 5, wherein the first metal layer is proximate to the light-emitting chip, grating periods of the metal line grid layer respectively corresponding to the first region, the second region, and the third region are the same, widths of the plurality of metal lines are the same, and a height of a metal line corresponding to the first region, a height of a metal line corresponding to the second region and a height of a metal line corresponding to the third region sequentially decrease.

11. The light-emitting substrate according to claim 4, wherein the grating structure comprises a first metal layer, a dielectric line grid layer, and a third metal layer sequentially arranged in a stacked manner, the dielectric line grid layer comprises a plurality of dielectric lines arranged at intervals, a grating period of the dielectric line grid layer corresponding to the first region, a grating period of the dielectric line grid layer corresponding to the second region and a grating period of the dielectric line grid layer corresponding to the third region sequentially decrease.

12. The light-emitting substrate according to claim 11, wherein a material of the dielectric line grid layer comprises SiO or SiN.

13. The light-emitting substrate according to claim 11, wherein a material of the dielectric line grid layer is a rigid substrate material or a flexible substrate material, the grating structure further comprises a first substrate between the dielectric line grid layer and the third metal layer, and the first substrate and the dielectric line grid layer are a one-piece structure.

14. A light-emitting substrate according to claim 1, wherein the driving backplane is a silicon-based driving backplane, and the light-emitting chip is a Micro LED or Mini LED.

15. A display apparatus, comprising the light-emitting substrate according to claim 1.
